(19) United States
(12) Patent Application Publication
(10) Pub. No.: US 2018/0087214 A1
(43) Pub. Date: Mar. 29, 2018

(54) REFRACTORY OXIDE COATED FIBER AND METHOD OF MAKING

(71) Applicant: FREE FORM FIBERS, LLC, Saratoga Springs, NY (US)

(72) Inventors: Shay L. HARRISON, East Schodack, NY (US); Marvin KESHNER, Sonora, CA (US); Joseph PEGNA, Saratoga Springs, NY (US); Erik G. VAALER, Redwood City, CA (US); John L. SCHNEITER, Cohoes, NY (US); Ram K. GODUGUCHINTA, Ballston Lake, NY (US); Kirk L. WILLIAMS, Saratoga Springs, NY (US)

(73) Assignee: FREE FORM FIBERS, LLC, Saratoga Springs, NY (US)

(21) Appl. No.: 15/718,206

(22) Filed: Sep. 28, 2017

Related U.S. Application Data
(60) Provisional application No. 62/400,711, filed on Sep. 28, 2016.

(51) Int. Cl. D06M 11/36; C23C 16/48; C23C 16/46; C23C 16/40

(52) U.S. Cl. CPC D06M 11/36; C23C 16/40; C23C 16/46; C23C 16/483

(57) ABSTRACT

A refractory oxide coated fiber is provided including a primary fiber material and a refractory oxide coating over the primary fiber material. Further, a method of making a refractory oxide coated fiber is provided, which includes: providing a first precursor-laden environment, the first precursor-laden environment including a primary precursor; promoting fiber growth within the first precursor-laden environment using laser heating; and providing a second precursor-laden environment to promote coating of the fiber, the second precursor-laden environment comprising a refractory oxide precursor, and the coating producing a refractory oxide coating over the fiber with a hexagonal microstructure.

### CROSS-REFERENCE TO RELATED APPLICATION

This application claims the benefit of U.S. provisional patent application Ser. No. 62/400,711, filed Sep. 28, 2016, entitled “Refractory Oxide Coated Fiber and Method of Making”, which is hereby incorporated herein by reference in its entirety.

### BACKGROUND

The present invention relates generally to the field of fibers for reinforcing materials and more specifically to the field of fibers having coatings.

In a wide variety of applications, fiber composite materials, incorporating fibers into a surrounding material matrix, provide higher structural performance than traditional, bulk (i.e., non-fiber) materials. To enhance the fracture toughness of the fiber composite material, coatings are typically applied to these fibers. While conventional coatings, such as graphite and boron nitride, do improve fracture toughness, these conventional coatings suffer from being susceptible to oxidation and to reaction with water vapor. When conventional non-layered oxide coatings have been used to improve oxidation and water vapor resistance, these conventional non-layered oxide coatings do not substantially improve fracture toughness.

### SUMMARY

Opportunities exist, therefore, to improve fiber composite material fracture toughness while simultaneously improving oxidation and water vapor resistance by providing a fiber with a protective refractory oxide coating.

The opportunities described above are addressed, in one aspect of the present invention, by a refractory oxide coated fiber comprising a primary fiber material and a refractory oxide coating over the primary fiber material. The refractory oxide coating has a hexagonal microstructure.

In another aspect, a method of making a refractory oxide coated fiber is provided. The method includes: providing a first precursor-laden environment, the first precursor-laden environment including a primary precursor; promoting a fiber growth within the first precursor-laden environment using laser heating; and providing a second precursor-laden environment to promote coating of the fiber, the second precursor-laden environment comprising a refractory oxide precursor, and the coating providing a refractory oxide coating over the fiber with a hexagonal microstructure.

Additional features and advantages are realized through the techniques of the present invention. Other embodiments and aspects of the invention are described in detail herein and are considered a part of the claimed invention.

### DRAWINGS

These and other features, aspects, and advantages of the present invention will become better understood when the following detailed description is read with reference to the accompanying drawings in which like characters represent like parts throughout the drawings, and wherein:

FIG. 1 is a schematic representation of a single-fiber reactor, showing a seed fiber substrate, a reactor cube into which precursor gases are delivered, a focused laser beam impinging on the seed fiber, and reactor windows that are transparent to the incoming laser beam wavelength and allow for, for instance, video monitoring of the process, in accordance with one or more aspects of the present invention;

FIG. 2 is a schematic view showing how LCVD can be massively parallelized by a multiplication of the laser beams, in accordance with one or more aspects of the present invention;

FIG. 3 depicts an example of parallel LCVD growth of carbon fibers, in accordance with one or more aspects of the present invention;

FIG. 4A is a simplified schematic of components of an LCVD system facilitating fabrication of a fiber with a desired chemical composition, of a single material or with performance enhancing additions, such as refractory material additives, in accordance with one or more aspects of the present invention;

FIG. 4B depicts one embodiment of a process for fabricating a fiber of desired chemical composition of a single material or with performance enhancing additions, such as refractory material additives, in accordance with one or more aspects of the present invention;

FIG. 5 depicts one embodiment of an apparatus for facilitating fabricating a plurality of refractory oxide coated fibers, in accordance with one or more aspects of the present invention;

FIG. 6 depicts one embodiment of a multi-stage system for forming an array of coated fibers produced via laser heating using laser chemical vapor deposition (LCVD), in accordance with one or more aspects of the present invention;

FIG. 7 is an exemplary SEM of an in situ coating showing the desired result of in situ coatings where fibers are separated, thereby preventing bridging, in accordance with one or more aspects of the present invention; and

FIG. 8 depicts one embodiment of a refractory oxide coated fiber, in accordance with one or more aspects of the present invention.

### DETAILED DESCRIPTION

Aspects of the present invention and certain features, advantages and details thereof, are explained more fully below with reference to the non-limiting example(s) illustrated in the accompanying drawings. Descriptions of well-known systems, devices, fabrication and processing techniques, etc., are omitted so as to not unnecessarily obscure the invention in detail. It should be understood, however, that the detailed description and the specific example(s), while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure. Note further that numerous inventive aspects and features are disclosed herein, and unless inconsistent, each disclosed aspect or feature is combinable with any other disclosed aspect or feature as desired for a particular application, for instance, for facilitating providing refractory oxide coated fibers and methods of making, as described herein.

Before describing the above-noted aspects further, note that the present invention incorporates or utilizes the following, alone or in any combination, and/or in combination with the subject matter of commonly assigned, International Patent Application No. PCT/US2015/037080, which published on Dec. 30, 2015, as PCT Patent Publication No. WO 2015/200257 A1, and with commonly assigned, U.S. patent application Ser. No. 15/114,504, filed Jul. 27, 2016, entitled: Contiguously Blended Nano-Scaled Multi-Phase Fibers”, which published on Dec. 1, 2016, as U.S. Patent Publication No. 2016/0347672 A1, and with commonly assigned, U.S. patent application Ser. No. 15/320,800, filed Dec. 21, 2016, entitled “An Additive Manufacturing Technology for the Fabrication and Characterization of Nuclear Reactor Fuel”, which published on Jul. 27, 2017, as U.S. Patent Publication No. 2017/0213604 A1, and with commonly assigned, U.S. patent application Ser. No. 15/592,408, filed May 11, 2017, entitled “Fiber Delivery Assembly and Method of Making”, and with commonly assigned, U.S. patent application Ser. No. 15/592,726, filed May 11, 2017, entitled “Multilayer Functional Fiber and Method of Making”, and with commonly assigned, U.S. patent application Ser. No. 15/631,243, filed Jun. 23, 2017, entitled “Nanofiber-Coated Fiber and Methods of Making”, each of which is hereby incorporated herein by reference in its entirety.

Fiber-reinforced composite materials are designed to concomitantly maximize strength and minimize weight. This is achieved by embedding high-strength low-density fibers into a low-density filler matrix in such a way that fibers channel and carry the structural stresses in composite structures. The matrix serves as a glue that holds fibers together and helps transfer loads in shear from fiber to fiber, but in fact the matrix material is not a structural element and carries but a negligible fraction of the overall structural load seen by a composite material.

Composites are thus engineered materials made up of a network of reinforcing fibers—sometimes woven, knitted or braided—held together by a matrix. Fibers are usually packaged as twisted multifilament yarns called “tows”. The matrix gives rise to three self-explanatory classes of composite materials: (1) Polymer Matrix Composites (PMCs), sometimes-called Organic Matrix Composites (OMCs); (2) Metal Matrix Composites (MMC's); and (3) Ceramic Matrix Composites (CMCs).

Such an approach to composite materials in which the tows are but a disorganized bundle of entangled filaments constrains the fibers to a purely structural role. A new approach to the fabrication of multilayered fibers called 1½-D printing allows for the formation of parallel, evenly spaced, parallel filaments. Together, this construct constitutes an arbitrary long ribbon of continuous filaments that allow the fiber to break out of their purely structural functions, and enable sweeping new designs in which the fibers contain embedded microsystems. This is described further in the above-referenced, commonly assigned, co-filed U.S. patent application Ser. No. 15/592,408.

This approach to fiber manufacturing has been proposed for example as a means to produce TRISO-inspired nuclear fuel embedded within fibers for subsequent embedding into a refractory matrix to form an accident tolerant CMC nuclear fuel, such as described in the above-referenced, commonly assigned PCT Patent Publication No. WO 2015/200257 A1. However, this is but one instance of possible new designs enabled by this technology.

At its core, 1½-D printing rests on the physical principles of Laser Induced Chemical Vapor Deposition to both print continuous filaments and deposit patterns coated onto the fiber. Commonly assigned, U.S. patent application Ser. No. 14/372,085, filed Jul. 14, 2014, entitled “High Strength Ceramic Fibers and Methods of Fabrication”, which published on Jan. 1, 2015, as U.S. Patent Publication No. 2015/0004393 A1, teaches how arrays of filaments can be laser-printed, with diameters potentially varying along their length. The above-referenced, PCT Patent Publication No. WO 2015/200257 A1 teaches how a laser incident to the ribbon can be used to write a pattern of coatings onto a substrate fiber by turning the laser on or off as the ribbon advances. It also teaches that coating thickness can be adjusted. Finally, the above-referenced, commonly assigned U.S. patent application Ser. No. 15/592,408, teaches how such ribbons of parallel filaments can be collected as ribbons onto a tape to enhance fiber volume fraction in the composite.

To implement 1½-D printing, Laser Induced Chemical Vapor Deposition (LCVD) was chosen as the fundamental Additive Manufacturing (AM) tool for its near material independence—an extremely rare property for AM processes. Such a process is said to be “Material Agnostic”. LCVD is a technique derived from CVD, used intensively in the microelectronics fabrication industry (aka “Chip Fab”). CVD builds up electronics-grade high-purity solid deposits from a gas precursor. In its 75+ year history, Chip Fab has accumulated an impressive library of chemical precursors for a wide range of materials, numbering in the tens of thousands. The main difference between CVD and LCVD resides in dimensionality and mass throughput. CVD is intended for 2-D film growth whereas LCVD is ideally suited for one-dimensional filamentary structures. The dimensionality difference means that deposition mechanisms are greatly enhanced for LCVD vs. CVD, leading to deposited mass fluxes (kg/m2 s) that are 3 to 9 orders of magnitude greater. For example, diamond-like carbon filaments have been measured at linear growth rates upwards of 13 cm/s, which represents a 9 order of magnitude increase in mass flux compared to thin film CVD of the same material. Finally, LCVD is essentially containerless, which virtually eliminates opportunities for material contamination by container or tool.

The following fundamental properties formally defines “1½-D Printing” AM
Material-agnostic ability to grow filaments.
Ability to vary diameter along the length of the filament, as illustrated in FIG. 10 of Pegna et al. (PCT Publication No. WO 2015/200257 A1).
Material-agnostic ability to vary composition along the length of the filament, as was demonstrated by Maxwell et al.
Material-agnostic ability to coat specific sections of filaments with a desired material, morphology and thickness; as illustrated by the nanoporous and other spot coatings shown in FIG. 11 of the above-referenced Pegna et al., PCT publication.

Disclosed herein, in part, is the concept of avoiding the use of polymeric precursors altogether by using laser-assisted chemical vapor deposition (LCVD) as is described in U.S. Pat. No. 5,786,023, entitled “Method and Apparatus for the Freeform Growth of Three-Dimensional Structures Using Pressurized Precursor Flows and Growth Rate Control”, by Maxwell and Pegna, the entirety of which is hereby incorporated by reference herein. In this process pure precursor gases (such as silane and ethylene in the case of SiC fiber production) are introduced into a reactor within which a suitable substrate such as glassy carbon is positioned, and laser light is focused onto the substrate. The heat generated by the focused laser beam breaks down the precursor gases locally, and the atomic species deposit onto the substrate surface and build up locally to form a fiber. If either the laser or the substrate is pulled away from this growth zone at the growth rate a continuous fiber filament will be produced with the very high purity of the starting gases. With this technique there are virtually no unwanted impurities, and in particular no performance-robbing oxygen.

Very pure fibers can be produced using LCVD, such as silicon carbide, boron carbide, silicon nitride and others. The inventors have discovered that if a material has been deposited using CVD, there is a good chance that fiber can be produced using LCVD. Unlike with liquid polymeric precursors, however, where the chemistry can be very involved and complicated even for relatively ‘simple’ materials such as those mentioned above, LCVD can also be used quite directly to produce novel mixes of solid phases of different materials that either cannot be made or have not been attempted using polymeric precursor and spinneret technology. Examples include fibers composed of silicon, carbon and nitrogen contributed by the precursor gases such as silane, ethylene and ammonia, respectively, where the resulting “composite” fiber contains tightly integrated phases of silicon carbide, silicon nitride and silicon carbonitrides depending on the relative concentrations of precursor gases in the reactor. Such new and unique fibers can exhibit very useful properties such as high temperature resistance, high strength and good creep resistance at low relative cost.

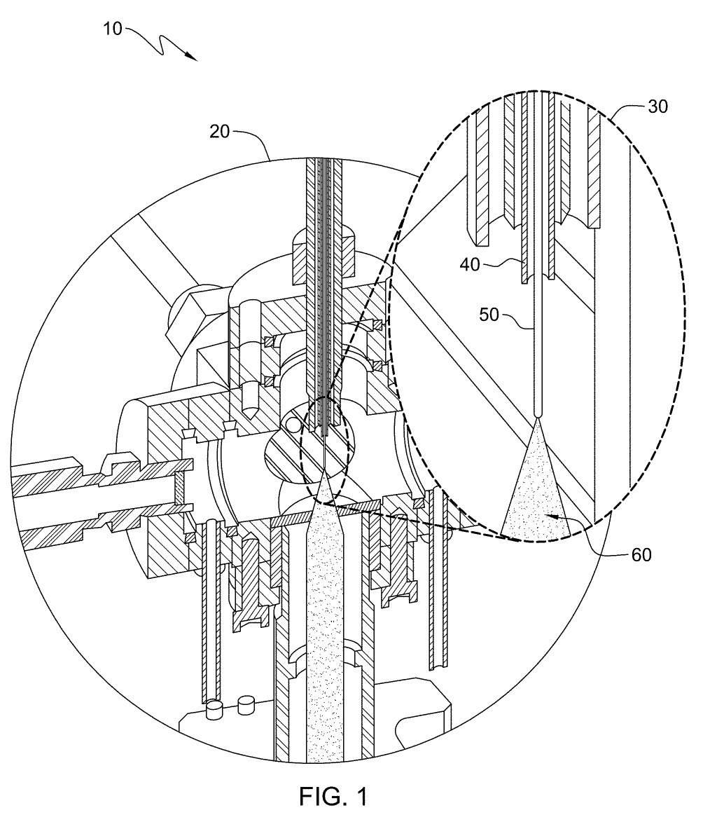

FIG. 1 shows a LCVD reactor into which a substrate seed fiber has been introduced, onto the tip of which a laser beam is focused. (It will be seen that the substrate may be any solid surface capable of being heated by the laser beam. It will further be seen that multiple lasers could be used simultaneously to produce multiple simultaneous fibers as is taught in International Patent Application Serial No. PCT/US2013/022053, which published on Dec. 5, 2013, as PCT Patent Publication No. WO 2013/180764 A1, and in U.S. Patent Publication No. 2015/0004393, the entireties of which are hereby incorporated by reference herein. In accordance with that Application, FIG. 1 more particularly shows a reactor 10; enlarged cutout view of reactor chamber 20; enlarged view of growth region 30. A self-seeded fiber 50 grows towards an oncoming coaxial laser 60 and is extracted through an extrusion microtube 40.

A mixture of precursor gases can be introduced at a desired relative partial pressure ratio and total pressure. The laser is turned on, generating a hot spot on the substrate, causing local precursor breakdown and local CVD growth in the direction of the temperature gradient, typically along the axis of the laser beam. Material will deposit and a fiber will grow, and if the fiber is withdrawn at the growth rate, the hot spot will remain largely stationary and the process can continue indefinitely, resulting in an arbitrarily long CVD-produced fiber.

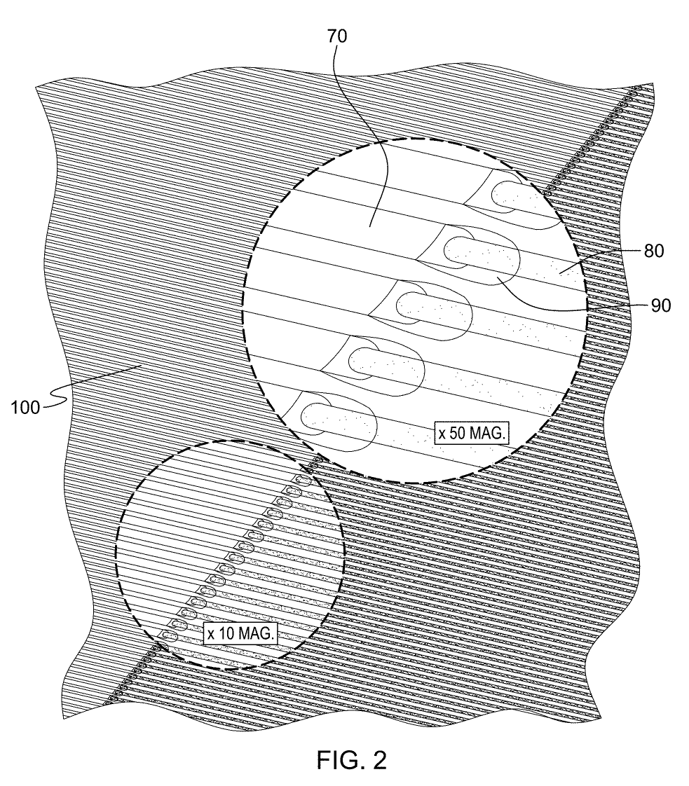

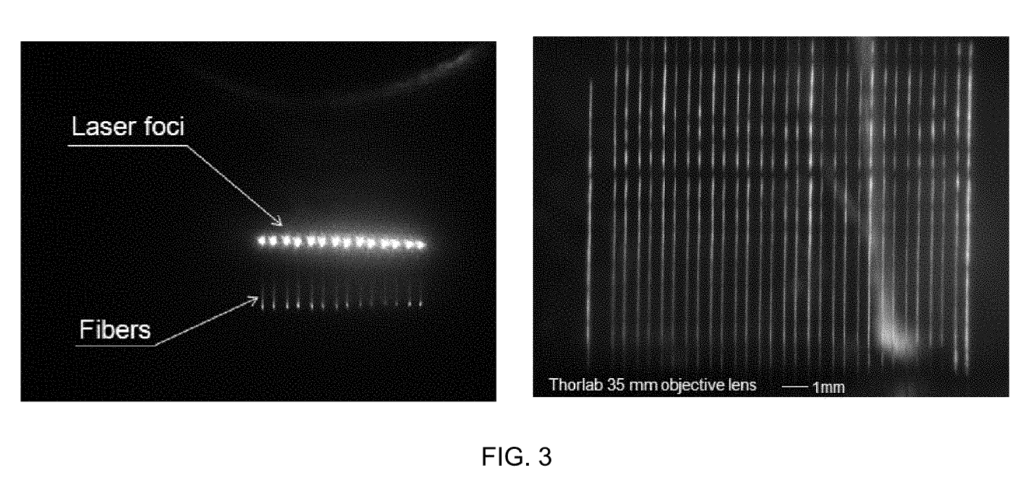

Also in accordance with that Application, a large array of independently controlled lasers can be provided, growing an equally large array of fibers 70 in parallel, as illustrated in FIG. 2, showing how fiber LCVD can be massively parallelized from a filament lattice 100 by multiplication of the laser beams 80 inducing a plasma 90 around the tip of each fiber 70. Using a Computer-to-Plate (CtP) (e.g., Quantum Well Intermixing (QWI)) laser array for LCVD is a scientific first, and so was the use of a shallow depth of focus. It provides very beneficial results. Sample carbon fibers, such as those shown in FIG. 3, were grown in parallel. FIG. 3 shows parallel LCVD growth of carbon fibers—Left: Fibers during growth and Right: Resulting free standing fibers 10-12 μm in diameter and about 5 mm long.

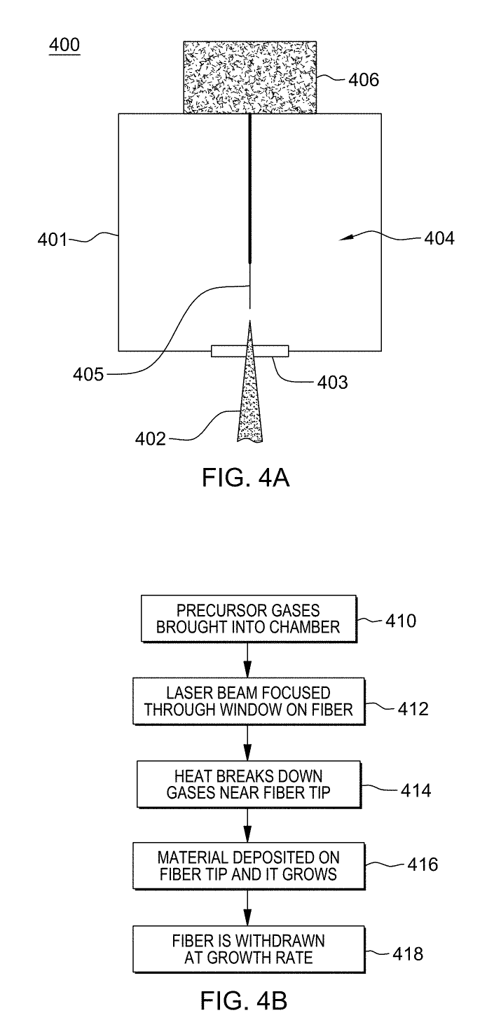

As discussed herein, laser-driven, chemical-vapor deposition (LCVD) technology is capable of forming high-performance ceramic and inorganic fibers for composite material systems. FIG. 1 discussed above is a schematic representation of a monofilament LCVD production process. FIG. 4A is a simplified view of an LCVD production system for producing a refractory oxide coated fiber, in accordance with one or more aspects of the present invention, and FIG. 4B depicts an exemplary process for producing a refractory oxide coated fiber, in accordance with one or more aspects of the present invention.

Referring to FIG. 4A, the LCVD system 400 shown includes a chamber 401 into which one or more lasers 402 are directed through one or more windows 403. Chamber 401 includes precursor gases 404 for facilitating producing a fiber 405 such as disclosed herein. A fiber extraction apparatus 406 facilitates withdrawing the fiber as it is produced within the chamber.

The deposition process may include bringing precursor gases into the chamber 410, as illustrated in FIG. 4B. For a given fabrication process, ratios of the precursor gases are selected and introduced into the chamber. The gases contain the atomic species that are to be deposited in the fiber format. For instance, silicon carbide fibers (SiC) may be formed from silicon-containing and carbon-containing gases, or a single gas that contains both atoms. In addition, a small laser beam is directed into the gas-containing chamber through a window that transmits the laser wavelength 412. This laser beam is focused onto an initiation site, which can be a fiber seed, a thin substrate, or any other solid component that will heat up upon being intersected by the beam and absorb its energy. At this hot spot 414, the precursor gases disassociate and, through certain chemical reaction steps, deposit a desired solid product. For instance, in the example above, the solid SiC deposit accreting together form the fiber 416. The fiber itself grows towards the laser source, and thus the fiber is pulled away and out of the reactor at an equivalent fiber growth rate 418. In this manner, the deposition zone remains at a constant physical position (i.e., the focal point of the laser beam), and deposition can continue indefinitely, as long as the laser beam is on and the supply of precursor gases is replenished.

As noted above, FIG. 2 provides a representation of a massive parallelization of the laser beam input, increased from a single beam to a multitude of individually controlled laser beams, to produce high-quality volume array of parallel fibers.

A single coating layer can be applied to the fibers. However, multiple coating layers may be applied to the base fibers in order to engineer additional environmental, thermal, or mechanical protection to the fiber performance. This can be accomplished by adding subsequent deposition stations to the LCVD production line, performing in the same manner as described herein.

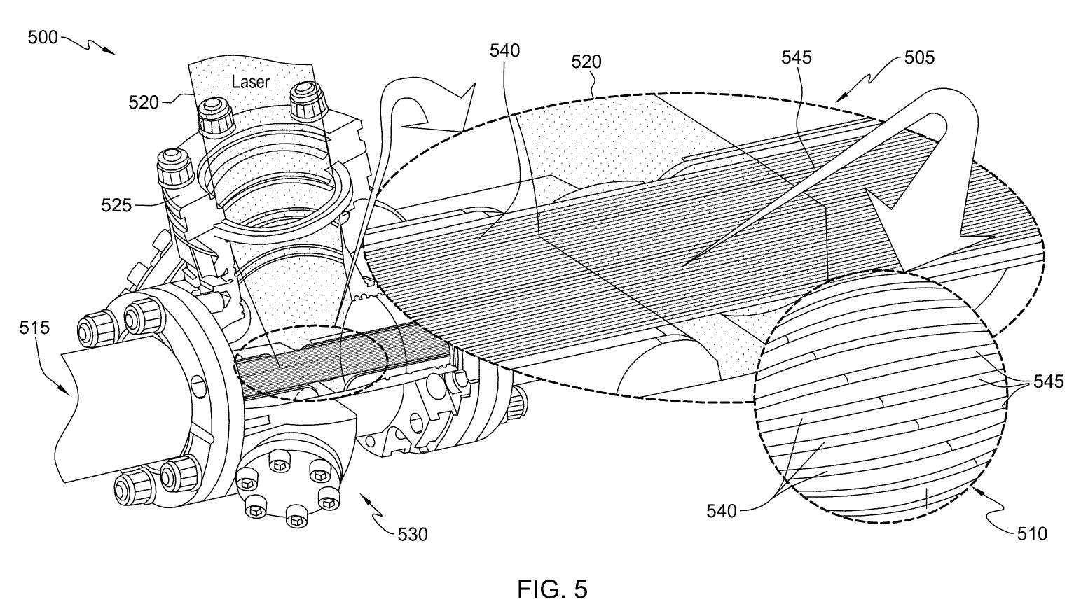

As noted, the embodiments of the processes disclosed herein may not only be applied to one fiber, but may be applied to multiple fibers in parallel. Each step of layer formation may be carried out in a separate deposition too, an example of which is depicted in FIG. 5, and the multiple fibers may be conveyed from one deposition to the next for the next layer to be deposited.

Once the parallel array of fibers are produced, the next processing step may involve the transition of the fiber feed to another downstream deposition station in which the interface coating is applied. FIG. 5 depicts one embodiment of such a coating deposition tool 500. This deposition tool 500 may convey multiple fibers 530 through a conveyer inlet into a deposition chamber 530. The deposition chamber may contain one or more precursor gases that may facilitate forming a coating layer. A laser 520 may be provided through a focusing chamber 525 (e.g., focusing lens). As the laser 520 interacts with the multiple fibers 540 and precursor gases, the desired layer may be deposited over the full length, or only portions of the length of the multiple fibers 545. In one example, the laser may be started and stopped at defined intervals as the multiple fibers pass through the deposition tool 500, thus controlling formation of the coating over portions of the multiple fibers 545, and leaving other portions unprocessed (e.g., non-fuel regions of the multiple fibers). The processed multiple fibers 545 may then be conveyed out of the deposition tool 500. The multiple fibers 545 may then be conveyed to another deposition tool, in which another coating layer may be formed, or may be finished and conveyed out of the tool entirely. For clarity, FIG. 5 includes close-up views 510 and 515 of the multiple fibers 540, 545, as the multiple fibers undergo LCVD processing to deposit a coating layer.

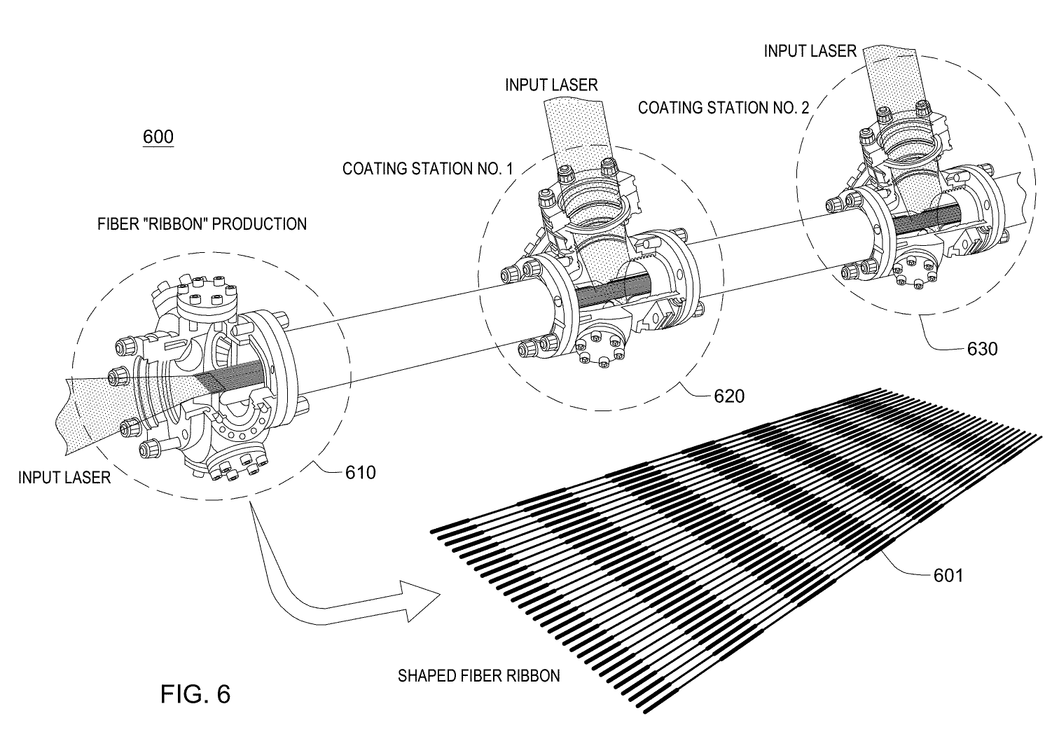

FIG. 6 depicts one embodiment of a system comprising multiple fiber production and coating deposition stages, in accordance with one or more aspects of the present invention. As illustrated, system 600 includes a fiber production stage 610, and in this example, a first coating stage 620 and a second coating stage 630. Each stage 610, 620, 630 may include, in one or more embodiments, a fiber production or deposition tool such as described herein, which utilizes LCVD processing with appropriate precursor gases within the deposition chamber. As illustrated in FIG. 6, a shaped, ribbon fiber 601 may be produced within the production environment illustrated. As shown in FIG. 6, the fiber (or fiber array) produced in fiber production stage 610 may be drawn through one or more subsequent coating stages to produce the final product, such as the refractory oxide coated fiber discussed herein.

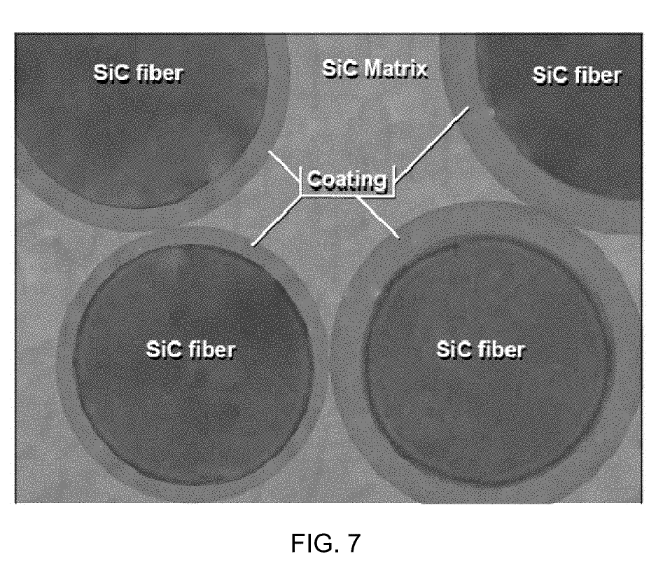

Ceramic matrix composite material systems are comprised of three essential components, that is, a reinforcing fiber, a matrix, and an interphase coating layer formed on the fiber surface that separates the fiber from the matrix. This system architecture ensures that the mechanical response of the overall composite is a graceful failure mechanism, and not a catastrophic, brittle response. The term “graceful failure” means that the composite possesses a certain amount of fracture toughness that allows some of the fracture energy from the propagating cracks to be consumed by the separation of the interphase layer from the reinforcing fiber. A representative image of such a composite system is depicted in FIG. 7, showing a SiC_{fiber}−SiCₘₐₜᵣᵢₓ system with a boron nitride (BN) coating.

The sliding mechanical response required for a fiber coating in a CMC in order to impart fracture toughness is derived from the underlying crystalline microstructure of the coating material. Materials with a hexagonal microstructure possess weak interlayer strength between parallel atomic layers, thereby allowing for the sliding mechanical action between the coating and the fiber surface it is applied to, and separating from which consumes the fracture energy of the propagating crack. The coating serves as an interphase layer between the fiber and the matrix, and by necessity should not be tightly adhered to the fiber surface, as this would promote a more ceramic (brittle) mechanical response by fully transferring the load to the fiber without achieving any fracture energy dissipation.

The use of a refractory oxide material as an interphase (coating) layer in a CMC material system is a novel approach to addressing many of the mechanical and chemical performance requirements necessary for a CMC deployed in a high temperature, aggressive chemical environment. Selection of a refractory oxide material that possesses the hexagonal crystalline microstructure enables the necessary sliding mechanical response for fracture toughness. The ability to withstand elevated temperatures (>1300° C.) without deleterious crystalline microstructural phase changes or chemical reaction degradation is of primary concern. One important aspect of this is resistance to oxidation (attack by oxygen) which a refractory oxide by definition is equipped to handle because it already contains atomic oxygen as part of its chemical composition. Another aspect is the resistance to formation of hydroxides from the chemical attack of water vapor (moisture) in the elevated temperature environment. The example of beryllium oxide (BeO) as a hexagonal microstructure, refractory oxide coating material is resilient against these types of environmental attacks because of it is already a thermodynamically stable oxide material, maintains a hexagonal microstructure up to approximately 2100° C., and does not form significant amounts of volatile hydroxide species (ex. Be(OH)₂) upon exposure to water vapor at elevated temperatures. Thus, BeO offers the opportunity for improved composite mechanical performance in aggressive (high temperature, moisture-laden) environments.

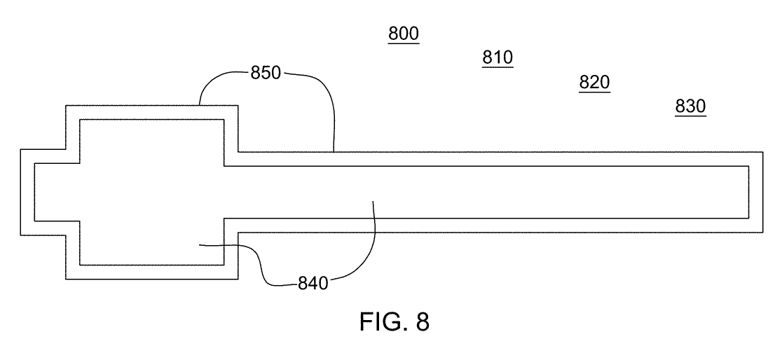

In accordance with one embodiment of the present invention, FIG. 8 illustrates a refractory oxide coated fiber 800 comprising a primary fiber material 840 and a refractory oxide coating 850 over primary fiber material 840. In one or more implementations, the coating over the primary fiber material has a hexagonal microstructure. The hexagonal microstructure possess a layered crystalline structure in which the strength of the interlayer bonding between parallel atomic planes is weak. A similar layered microstructure compatible with the desired coating material performance in a CMC would be the orthorhombic perovskite crystal structure, which is also included herein by the phrase “hexagonal microstructure”.

In a more detailed embodiment, primary fiber material 840 comprises an ordinarily solid material selected from a group consisting of boron, carbon, aluminum, silicon, titanium, zirconium, niobium, molybdenum, hafnium, tantalum, tungsten, rhenium, osmium, nitrogen, oxygen, and combinations thereof. As used herein, an “ordinarily solid material” means a material that is solid at a temperature of 20 degrees Celsius and a pressure of 1 atmosphere.

In another more detailed embodiment, the refractory oxide coating 850 having the hexagonal microstructure comprises beryllium oxide.

In an alternative more detailed embodiment, primary fiber material 840 comprises silicon carbide, and refractory oxide coating 850 comprises beryllium oxide.

In another more detailed embodiment, refractory oxide coated fiber 800 has a substantially non-uniform diameter.

In accordance with another aspect of the present invention, a method of making a refractory oxide coated fiber 800 comprises acts of providing a precursor-laden environment 810 and promoting fiber growth using laser heating, the precursor-laden environment 810 comprising a primary precursor material 820 and a refractory oxide precursor material 830.

In a more detailed embodiment, precursor-laden environment 810 comprises a material selected from a group consisting of gases, liquids, critical fluids, supercritical fluids, and combinations thereof.

In another more detailed embodiment, primary precursor material 820 is a precursor for a primary fiber material 840. Primary fiber material 840 comprises an ordinarily solid material selected from a group consisting of boron, carbon, aluminum, silicon, titanium, zirconium, niobium, molybdenum, hafnium, tantalum, tungsten, rhenium, osmium, nitrogen, oxygen, and combinations thereof.

In another more detailed embodiment, refractory oxide precursor material 830 comprises a precursor for beryllium oxide.

In an alternative embodiment, primary precursor material 820 comprises a precursor for silicon carbide, and refractory oxide precursor material 830 comprises a precursor for beryllium oxide.

In another more detailed embodiment, the act of promoting fiber growth using laser heating comprises modulating the laser heating such that refractory oxide coated fiber 800 has a substantially non-uniform diameter. For instance, user-directed inputs for the LCVD process growth parameters, such as input laser power and precursor gas characteristics, provide exquisite control over the final formed fiber chemical and physical properties. For instance, these growth parameters can be altered to impart variations in the fiber diameter dimension. In effect, the fiber diameter may be changed from a thinner-to-thicker-to-thinner section (or vice versa), which can be repeated in a desired precocity or designed in some manner to impart desired physical properties for the fibers in the overall composite performance.

Those skilled in art will note from the above description that provided herein are a refractory oxide coated fiber, and a process for producing refractory oxide coated fibers. Advantageously, the coating provided has a hexagonal nature, which is a significant property to the material's usefulness as a component of the ceramic matrix composite (CMC) material system in the composite's overall mechanical performance. The term “hexagonal” refers to a hexagonal microstructure or, as noted, the orthorhombic perovskite crystal structure. In material science terms, the microstructure achieved is hexagonal close-packed (HCP), which in general means it has stronger mechanical properties in the x-y plane of crystalline structure, but significantly weaker links between adjacent parallel z planes. This directional weakness is advantageous for the interphase coating because it allows for sliding between the z planes, which provides the path for a propagating crack to progress along, and therefore acts to enhance the fracture toughness of the composite.

Those skilled in the art will also note from the above description that provided herein are refractory oxide coated fibers and methods of fabrication thereof. For instance, the refractory oxide coated fiber may include a primary fiber material, and a refractory oxide coating over the primary fiber material. The refractory oxide coating has a hexagonal microstructure. In one or more embodiments, the primary fiber material includes an ordinarily solid material selected from a group consisting of boron, carbon, aluminum, silicon, titanium, zirconium, niobium, molybdenum, hafnium, tantalum, tungsten, rhenium, osmium, nitrogen, oxygen, and combinations thereof.

In one or more embodiments, the refractory oxide coating with hexagonal microstructure may include beryllium oxide. In one or more other embodiments, the primary fiber material may include silicon carbide, and the refractory oxide coating may include beryllium oxide. In one or more embodiments, the refractory oxide coated fiber may have a substantially non-uniform diameter.

In one or more other aspects, a method of making a refractory oxide coated fiber is provided, which includes: providing a first precursor-laden environment, the first precursor-laden environment including a primary precursor; promoting a fiber growth within the first precursor-laden environment using laser heating; and providing a second precursor-laden environment to promote coating of the fiber, the second precursor-laden environment comprising a refractory oxide precursor, and the coating providing a refractory oxide coating over the fiber with a hexagonal microstructure.

In one or more implementations, the first and/or second precursor-laden environments include a precursor selected from a group consisting of gases, liquids, critical fluids, super-critical fluids, and combinations thereof. Further, the primary precursor may be a precursor for a primary fiber material. The primary fiber material may include an ordinarily solid material selected from a group consisting of boron, carbon, aluminum, silicon, titanium, zirconium, niobium, molybdenum, hafnium, tantalum, tungsten, rhenium, osmium, nitrogen, oxygen, and combinations thereof.

In one or more implementations, the refractory oxide precursor material includes a precursor for beryllium oxide. In one or more other embodiments, the primary precursor material includes a precursor for silicon carbide, and the refractory oxide precursor includes a precursor for beryllium oxide.

In one or more embodiments, the promoting fiber growth using laser heating may include modulating the laser heating such that the refractory oxide coated fiber has a substantially non-uniform diameter.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

We claim:

1. A refractory oxide coated fiber comprising:
a primary fiber material; and
a refractory oxide coating over the primary fiber material, the refractory oxide coating having a hexagonal microstructure.

2. The refractory oxide coated fiber of claim 1, wherein the primary fiber material comprises an ordinarily solid material selected from a group consisting of boron, carbon, aluminum, silicon, titanium, zirconium, niobium, molybdenum, hafnium, tantalum, tungsten, rhenium, osmium, nitrogen, oxygen, and combinations thereof.

3. The refractory oxide coated fiber of claim 1, wherein the refractory oxide coating with hexagonal microstructure comprises beryllium oxide.

4. The refractory oxide coated fiber of claim 1, wherein the primary fiber material comprises silicon carbide, and the refractory oxide coating with hexagonal microstructure comprises beryllium oxide.

5. The refractory oxide coated fiber of claim 1, wherein the refractory oxide coated fiber has a substantially non-uniform diameter.

6. A method of making a refractory oxide coated fiber, the method comprising:
providing a first precursor-laden environment, the first precursor-laden environment comprising a primary precursor;
promoting a fiber growth within the first precursor-laden environment using laser heating; and
providing a second precursor-laden environment to promote coating of the fiber, the second precursor-laden environment comprising a refractory oxide precursor, and the coating providing a refractory oxide coating over the fiber with a hexagonal microstructure.

7. The method of claim 6, wherein the first precursor-laden environment comprises a precursor selected from a group consisting of gases, liquids, critical fluids, supercritical fluids, and combinations thereof.

8. The method of claim 6, wherein the second precursor-laden environment comprises a precursor selected from a group consisting of gases, liquids, critical fluids, super-critical fluids, and combinations thereof.

9. The method of claim 6, wherein the primary precursor is a precursor for a primary fiber material, the primary fiber material comprising an ordinarily solid material selected from a group consisting of boron, carbon, aluminum, silicon, titanium, zirconium, niobium, molybdenum, hafnium, tantalum, tungsten, rhenium, osmium, nitrogen, oxygen, and combinations thereof.

10. The method of claim 6, wherein the refractory oxide precursor comprises a precursor for beryllium oxide.

11. The method of claim 6, wherein the primary precursor comprises a precursor for silicon carbide, and the refractory oxide precursor comprises a precursor for beryllium oxide.

12. The method of claim 6, wherein the promoting fiber growth using laser heating comprises modulating the laser heating such that the refractory oxide coated fiber has a substantially non-uniform diameter.
